(19) United States
(12) Patent Application Publication
(10) Pub. No.: US 2023/0261482 A1
(43) Pub. Date: Aug. 17, 2023

(54) CELL BALANCING CIRCUITRY

(71) Applicant: Cirrus Logic International Semiconductor Ltd., Edinburgh (GB)

(72) Inventor: John P. LESSO, Edinburgh (GB)

(73) Assignee: Cirrus Logic International Semiconductor Ltd., Edinburgh (GB)

(21) Appl. No.: 18/104,337

(22) Filed: Feb. 1, 2023

Related U.S. Application Data
(60) Provisional application No. 63/309,073, filed on Feb. 11, 2022.

(30) Foreign Application Priority Data
Feb. 22, 2022 (GB) 2202378.2

(51) Int. Cl. H02J 7/00; H02J 7/34

(52) U.S. Cl. CPC H02J 7/0019; H02J 7/0047; H02J 7/345

(57) ABSTRACT

Cell balancing circuitry for balancing a set of cells, the cell balancing circuitry comprising: a switch network configured for coupling to the cells; a set of capacitors coupled in parallel between the switch network and a common node; and detection circuitry configured to detect a fault in a capacitor of the set of capacitors based on a voltage at the common node.

### FIELD OF THE INVENTION

The present disclosure relates to cell balancing circuitry for balancing a voltage and/or a state of charge between cells in a battery or battery pack.

### BACKGROUND

Battery packs are used in a wide variety of applications to provide electrical power. For example, portable devices (e.g., laptop computers, cordless power tools and the like) and larger devices such as electric scooters and bicycles may include a rechargeable battery pack to power the device. One of the largest areas of growth in demand for battery packs is electric vehicles (EVs), such as electric cars, vans, motorcycles and goods vehicles.

A battery pack is typically made up of a number of connected modules, each containing a plurality of individual cells that are connected together in series, parallel or series/parallel combinations in order to achieve a desired nominal output voltage and battery capacity.

In use of a battery pack of the kind described above, it is important that discharging stops when any one of the individual cells reaches a defined lower limit, i.e., a lower threshold, of voltage or charge. Continued use of the battery pack beyond this point risks permanently damaging the particular cell that has reached the lower limit of voltage or charge through excessive discharge of that cell, making it impossible subsequently to recharge the cell effectively. Similarly, when the battery pack is being charged, charging must stop when the voltage of any one of the individual cells reaches a defined upper limit, i.e., an upper threshold. Continued charging after this upper limit has been reached risks permanently damaging the particular cell that has reached the upper limit, or more severe consequences such as thermal runaway for example.

Although the nominal capacity of all of the cells in a battery pack may be the same, inevitable variations in capacity between cells (resulting from, for example, manufacturing tolerances, cell aging, variations in the temperature to which the individual cells are exposed and the like) will result in variations in capacity between cells, resulting in non-uniform charging and discharging characteristics between the cells of the battery pack, such that some cells will reach the lower limit of voltage or charge during use, and/or the upper voltage limit during charging, more quickly than others. As will be appreciated, however, constraining use of the battery pack based on a discharge characteristic, such as the discharge rate, of a particular cell with the lowest capacity will lead to an unnecessary reduction in the usable energy of the battery pack between charges, since the other cells will still have capacity when the particular cell has reached the lower limit of voltage or charge. Similarly, constraining charging of the battery pack based on a charging characteristic, such as the charging rate, of a particular cell which reaches the upper voltage limit first will result in an unnecessary reduction in the usable energy of the battery pack between charges, because charging of the battery pack will stop before all of the cells are fully charged.

To mitigate these issues, cell balancing strategies may be used. The aim of cell balancing is to equalise (to a desired extent) the state of charge/discharge and/or the voltage of each cell in the battery pack.

FIGS. 1a-1d are schematic diagrams illustrating a charge-shuttling cell balancing system for balancing or equalising the voltage and/or state of charge of a set of series-connected cells of a battery or battery pack.

As shown generally at 100 in FIG. 1a, a cell balancing system for balancing or equalising (at least partially) a voltage and/or state of charge of a set of cells 110 comprises a switch network 120, a set of capacitors 130 and controller circuitry 140 which receives a clock signal CLK.

In this example the set of cells 110 comprises first to third series-connected cells 112-116. The set of capacitors 130 comprises at least one capacitor 132, and the switch network 120 comprises a plurality of switches for selectively coupling the capacitor(s) of the set of capacitors 130 to the cells 112-116 of the set of cells 110.

The operation of the cell balancing system 100 is illustrated in FIGS. 1b-1d, in which for clarity the switch network 120 is not shown.

During a first phase of operation Φ1, which is synchronised to a first cycle of the clock signal CLK, the controller circuitry 140 issues appropriate control signals to the switch network 120 to cause switches to close to couple a capacitor 132 of the set of capacitors 130 in parallel with the third cell 116 of the set of cells 110. Current can therefore flow between the third cell 116 and the capacitor 132. If a voltage across the third cell 116 exceeds a voltage across the capacitor 132, current will flow from the third cell 116 to the capacitor 132, thereby charging up the capacitor 132. Conversely, if the voltage across the capacitor 132 exceeds the voltage across the third cell 116, current will flow from the capacitor 132 to the third cell 116, charging up the third cell 116.

During a second phase of operation Φ2, which is synchronised to a second cycle of the clock signal CLK, the controller circuitry 140 issues appropriate control signals to the switch network 120 to cause switches to close to couple the capacitor 132 in parallel with the second cell 114 of the set of cells 110 (and to open the necessary switches to decouple the capacitor 132 from the first cell 112). Current can therefore flow between the second cell 114 and the capacitor 132. If the voltage across the capacitor 132 exceeds the voltage across the second cell 114, current will flow from the capacitor 132 to the second cell 114, charging up the second cell 114. Conversely, if the voltage across the second cell 114 exceeds a voltage across the capacitor 132, current will flow from the second cell 114 to the capacitor 132, thereby charging up the capacitor 132.

During a third phase of operation Φ3, which is synchronised to a third cycle of the clock signal CLK, the controller circuitry 140 issues appropriate control signals to the switch network 120 to cause switches to close to couple the capacitor 132 in parallel with the first cell 112 of the set of cells 110 (and to open the necessary switches to decouple the capacitor 132 from the second cell 114). Current can therefore flow between the first cell 112 and the capacitor 132. If the voltage across the capacitor 132 exceeds the voltage across the first cell 112, current will flow from the capacitor 132 to the first cell 112, charging up the first cell 112. Conversely, if the voltage across the first cell 112 exceeds a voltage across the capacitor 132, current will flow from the first cell 112 to the capacitor 132, thereby charging up the capacitor 132.

By cycling through the phases Φ1-Φ3, charge can be transferred between the cells 112-116 via the capacitor 132, to equalise or balance, at least partially, the voltage and/or state of charge of the cells 110.

Although the charge shuttling cell balancing system 100 of FIGS. 1a-1d can be effective in balancing the voltage and/or state of charge of the cells 112-116, achieving a desired level of balancing or equalisation of the cells can be slow, particularly where the set of cells includes a large number of individual cells.

Additionally, in the cell balancing system 100 there is a risk that the cells could be damaged in the event that the capacitor 132 fails or develops a fault. If the capacitor 132 fails as a short circuit, then the cell to which it is connected at the time of the failure will be short circuited (i.e., its positive terminal will be coupled directly to its negative terminal via the short circuited capacitor 132), which could lead to damage to that cell.

### SUMMARY

According to a first aspect, the invention provides cell balancing circuitry for balancing a set of cells, the cell balancing circuitry comprising:
a switch network configured for coupling to the cells;
a set of capacitors coupled in parallel between the switch network and a common node; and
detection circuitry configured to detect a fault in a capacitor of the set of capacitors based on a voltage at the common node.

The detection circuitry may be configured to output a signal indicative of a fault in a capacitor if the voltage at the common node differs from an expected voltage.

The switch network may comprise a plurality of switches configured to selectively couple a first terminal of each capacitor of the set of capacitors to a first terminal or a second terminal of a respective different cell of the set of cells.

The cell balancing may further comprise control circuitry configured to control operation of the plurality of switches of the switch network.

The control circuitry may be configured to receive a clock signal and to synchronise operation of the switches to cycles of the clock signal.

The control circuitry may be operable, when the switch network is coupled to a set of cells prior to operation of the cell balancing circuitry, or in response to detection of a fault in a capacitor during operation of the cell balancing circuitry, to:
decouple the set of capacitors from the set of cells; and
subsequently couple a capacitor of the set of capacitors to the set of cells.

The detection circuitry may be operable to monitor the voltage at the common node and to identify that the capacitor is affected by the fault if the voltage at the common node changes when the capacitor is coupled to the set of cells.

The cell balancing circuitry may be operable in a first phase in which a first subset of the set of cells is coupled to the set of capacitors and a second phase in which a second subset of the set of cells, different from the first subset, is coupled to the set of capacitors.

The detection circuitry may be configured to monitor a voltage at the common node during operation of the cell balancing circuitry and to identify that a capacitor of the set of capacitors is affected by a fault if a predetermined modulation of the voltage at the common node is detected in successive phases of operation.

The control circuitry may be configured to decouple the identified capacitor from the set of cells.

The control circuitry may be configured to hold open switches associated with the identified capacitor, for example.

The cell balancing circuitry may further comprise a voltage source for supplying a bias voltage to the common node.

According to a second aspect, the invention provides a method for detecting a fault in a capacitor of a set of capacitors of cell balancing circuitry comprising a switch network and a set of capacitors in which each capacitor of the set of capacitors is coupled in parallel between the switch network and a common node, the method comprising:
with the cell balancing circuitry coupled to a set of cells, closing a switch of the switch network in turn to couple a capacitor of the set of capacitors to the common node;
detecting a voltage at the common node when the capacitor is coupled to the common node; and
if the voltage at the common node differs from an expected voltage or voltage range when the capacitor is coupled to the common node, identifying that the capacitor is affected by a fault.

According to a third aspect, the invention provides a method for detecting a fault in a capacitor of a set of capacitors of cell balancing circuitry comprising a switch network and a set of capacitors in which each capacitor of the set of capacitors is coupled in parallel between the switch network and a common node and the cell balancing circuitry is operable in a first phase in which a first subset of the set of cells is coupled to the set of capacitors and a second phase in which a second subset of the set of cells, different from the first subset, is coupled to the set of capacitors, the method comprising:
monitoring a voltage at the common node during operation of the cell balancing circuitry; and
identifying that a capacitor of the set of capacitors is affected by a fault if a predetermined modulation of the voltage at the common node is detected in successive phases of operation.

According to a fourth aspect, the invention provides an integrated circuit comprising cell balancing circuitry according to the first aspect.

According to a fifth aspect, the invention provides a host device comprising cell balancing circuitry according to the first aspect.

The host device may comprise an electric vehicle, an electric bicycle, a wheelchair, an electric scooter, a cordless power tool, a computing device, a laptop, notebook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

According to a sixth aspect, the invention provides a battery or battery pack comprising cell balancing circuitry according to the first aspect.

According to a seventh aspect, the invention provides an integrated circuit comprising a switch network for cell balancing circuitry according to the first aspect.

The integrated circuit may further comprise control circuitry for controlling the switch network.

According to a further aspect, the invention provides a module comprising an integrated circuit according to the seventh aspect and a set of capacitors.

### BRIEF DESCRIPTION OF THE DRAWINGS

Embodiments of the invention will now be described, strictly by way of example only, with reference to the accompanying drawings, of which:

FIGS. 1a-1d schematically illustrate the structure and operation of a charge shuttling cell balancing system;

FIG. 2a-2c schematically illustrate the structure and operation of an alternative cell balancing system;

FIGS. 3a-3f schematically illustrate the effects of a short circuit failure of one of the capacitors of the cell balancing system of FIGS. 2a; and

FIG. 4 is a schematic representation of a cell balancing system according to the present disclosure.

### DETAILED DESCRIPTION

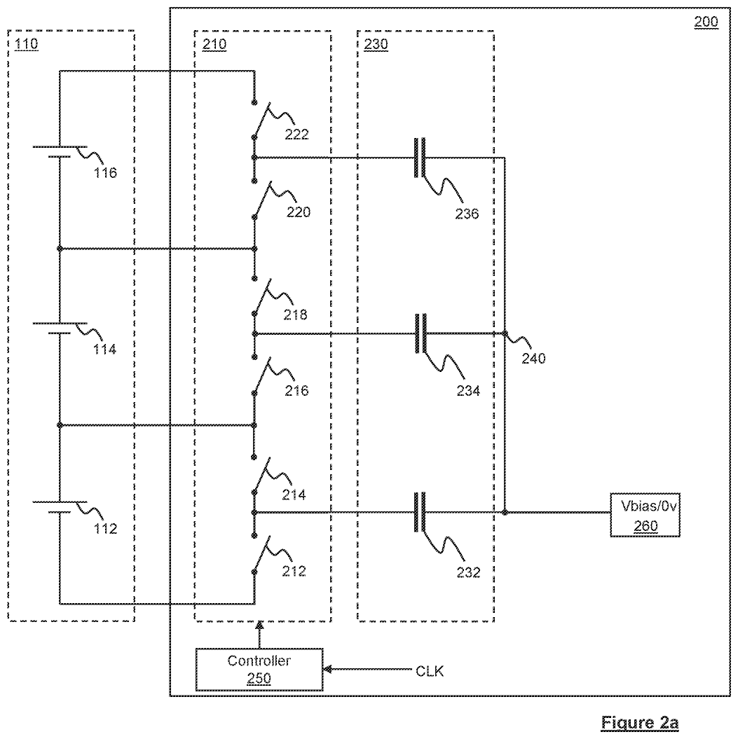

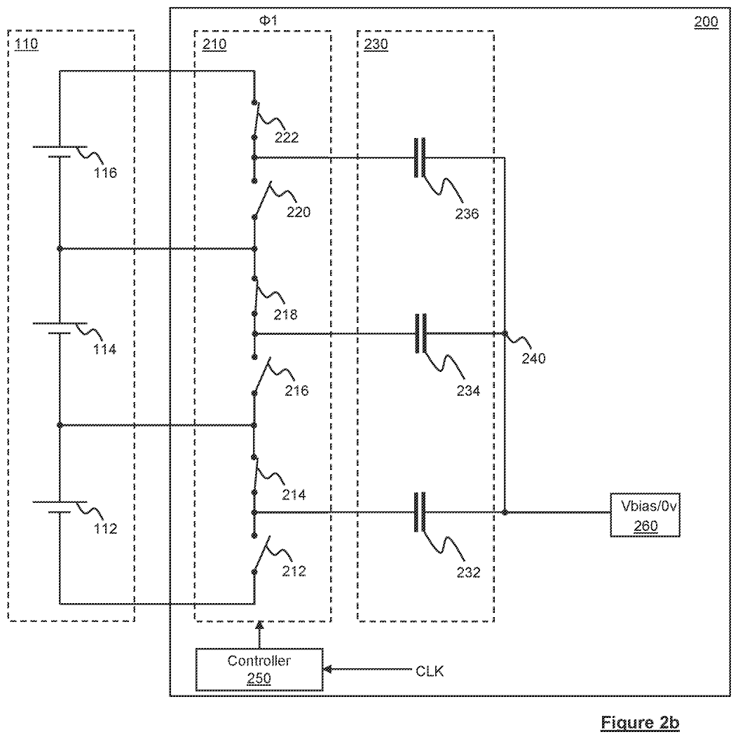

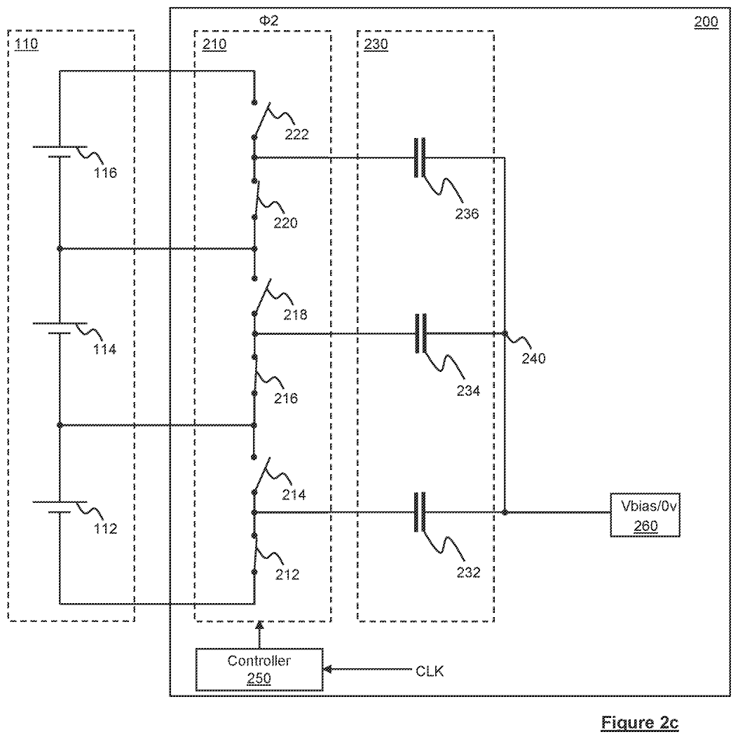

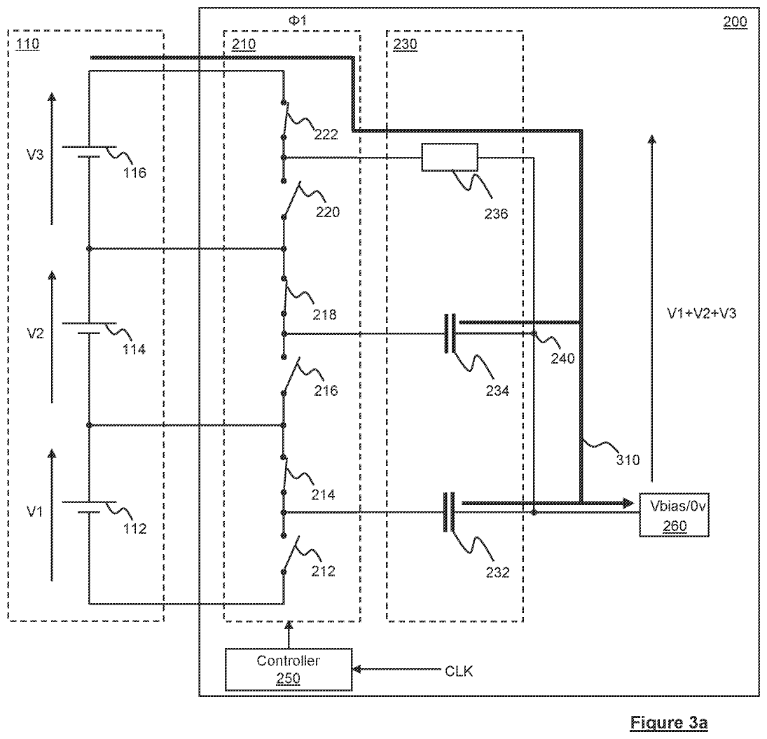

FIG. 2a is a schematic illustration of alternative cell balancing circuitry. The circuitry, shown generally at 200 in FIG. 2a, is based on a switched capacitor architecture, and is operable to balance or equalise, at least partially, a state of charge (SoC) and/or voltage of a set 110 comprising a plurality N (in this example first to third) of series-connected cells 112, 114, 116.

The cell balancing circuitry 200 in this example comprises a switch network 210 comprising first to sixth series-connected switches 212-222, a set of capacitors 230 comprising first to third capacitors 232-236 and control circuitry 250 to control the operation of the switches 212-222. The switches 212-222 may be electrically controllable switching devices such as MOSFETs, for example. The control circuitry 250 may be implemented by a microprocessor, microcontroller, state machine or the like.

More generally, for a set 110 comprising N cells, the cell balancing circuitry 200 will comprise N capacitors and a switch network comprising 2N switches. In the particular example shown in FIG. 2a, N=3.

A first terminal of the first capacitor 232 is coupled to a node between the first and second switches 212, 214, such that when the set of cells is coupled to the switch network as shown in FIG. 2a the first capacitor 232 can be selectively coupled to either a first (lower) terminal of the first cell 112 (by closing the first switch 212) or a second (upper) terminal of the first cell 112 (by closing the second switch 214). A second terminal of the first capacitor 232 is coupled to a common node 240.

Similarly, a first terminal of the second capacitor 234 is coupled to a node between the third and fourth switches 216, 218, such that when the set of cells is coupled to the switch network as shown in FIG. 2a the second capacitor 234 can be selectively coupled to either a first (lower) terminal of the second cell 114 (by closing the third switch 216) or a second (upper) terminal of the second cell 114 (by closing the fourth switch 218). A second terminal of the second capacitor 824 is coupled to the common node 240.

A first terminal of the third capacitor 236 is coupled to a node between the fifth and sixth switches 220, 222, such that when the set of cells is coupled to the switch network as shown in FIG. 2a the third capacitor 236 can be selectively coupled to either a first (lower) terminal of the third cell 116 (by closing the fifth switch 220) or a second (upper) terminal of the third cell 116 (by closing the sixth switch 222). A second terminal of the third capacitor 236 is coupled to the common node 240.

In some examples the common node 240 may be coupled to a voltage source 260 that supplies a bias voltage Vbias, or to a 0v or ground node.

The cell balancing circuitry 200 may operate continuously while the set of cells 110 is in use (e.g., to power a device of the kind discussed above) and/or while the set of cells 110 is charging, or may operate intermittently or periodically during use and/or charging of the set of cells 110.

In operation of the cell balancing circuitry 200, the switches 212-222 are controlled by the control circuitry 250 to switch on and off in a predefined sequence to charge and discharge the capacitors 232-236 in order to balance or equalise (at least partially) the cells 112-116. Operation of the switches is synchronised to a clock signal CLK that is received or internally generated by the control circuitry 250.

As shown in FIG. 2b, during a first phase Φ1 of operation of the cell balancing circuitry 200 (which is synchronised to a first cycle of the clock signal CLK) the first, third and fifth switches 212, 216, 220 are open and the second, fourth and sixth switches 214, 218, 222 are closed (in response to appropriate control signals from the control circuitry 250).

This has the effect of coupling the first, second and third capacitors 232-236 to the second and third cells 114, 116. More specifically, a series combination of the second and third capacitors 234, 236 is coupled in parallel with the third cell 116, a series combination of the first and third capacitors 232, 236 is coupled in parallel with a series combination of the second and third cells 114, 116, and a series combination of the first and second capacitors 232, 234 is coupled in parallel with the second cell 114.

Thus, during the first phase Φ1 current can flow between the second and third cells 114, 116 and the capacitors 232-236. The direction of current flow will depend upon the voltage across each of the second and third cells 114, 116 and across each of the capacitors 232-236. If, at the start of the first phase, the second and third cells 114, 116 are at a relatively high voltage or state of charge and the first, second and third capacitors 232-236 are all at a relatively low voltage or state of charge, then during the first phase current will flow from the second and third cells 114, 116 to the capacitors 236-236, thereby charging the capacitors 232-236.

As shown in FIG. 2c, during a second phase Φ2 of operation of the cell balancing circuitry 200 (which is synchronised to a second cycle of the clock signal CLK) the first, third and fifth switches 212, 216, 220 are closed and the second, fourth and sixth switches 214, 218, 222 are opened (in response to appropriate control signals from the control circuitry 250). This has the effect of coupling the first, second and third capacitors 232-236 to the first and second cells 112, 114. More specifically, a series combination of the second and third capacitors 234, 236 is coupled in parallel with the second cell 114, a series combination of the first and third capacitors 232, 236 is coupled in parallel with a series combination of the first and second cells 112, 114, and a series combination of the first and second capacitors 232, 234 is coupled in parallel with the first cell 112.

Thus, during the second phase Φ2 current can flow between the first and second cells 112, 114 and the capacitors 232-236. The direction of current flow will depend upon the voltage across each of the first and second cells 112, 114 and across each of the capacitors 232-236. If, at the start of the second phase, the first, second and third capacitors 232-236 are at a relatively high voltage or state of charge and the first and second cells 112, 114 are at a relatively low voltage or state of charge, then during the second phase, current will flow from the capacitors 232-236, thereby charging the first and second cells 112, 114.

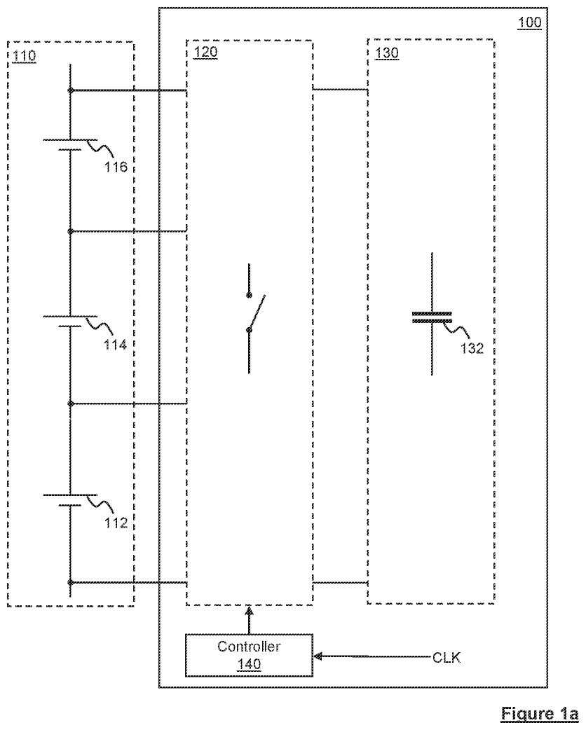

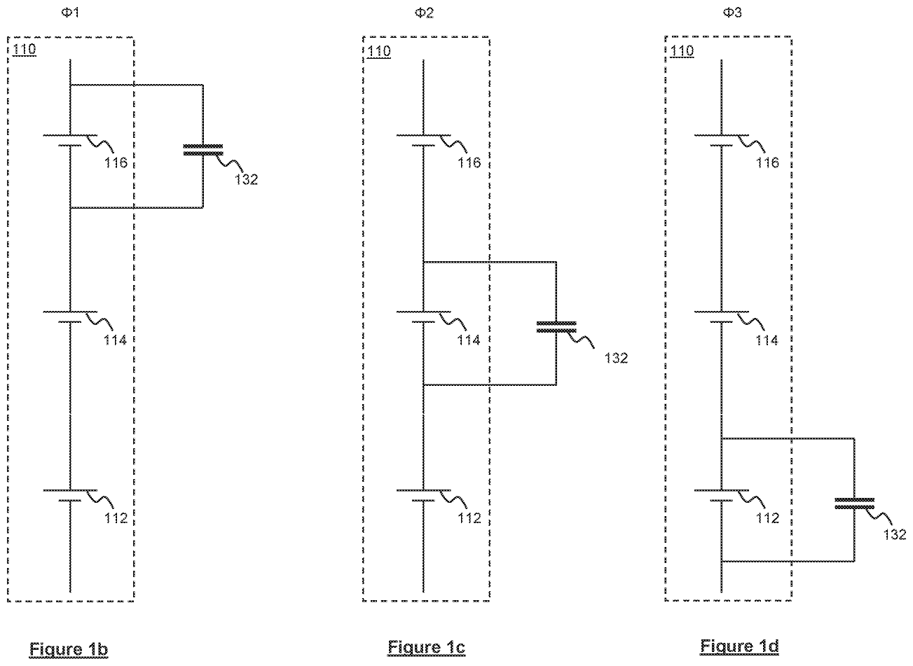

As will be appreciated, in the cell balancing circuitry 200 shown in FIGS. 2a-2c charge is transferred between different subsets of the set of cells 110 and the capacitors 232-236 in consecutive phases Φ1, Φ2. For a set of N cells, charge is transferred between different subsets of N−1 adjacent cells in consecutive phases Φ1, Φ2 of operation of the cell balancing circuitry 200. Thus, in the cell balancing circuitry 200 the process of balancing or equalising the cells 112-116 takes fewer clock cycles than in the cell balancing system 100 of FIG. 1a.

It will be appreciated that in a practical implementation of the concept illustrated in FIGS. 2a-2c the set of cells 110 may comprise more (e.g., 8 or 16) series-connected cells, and thus the cell balancing circuitry 200 will include more than three capacitors and more than six switches.

As a general rule, for a set of N cells, the cell balancing circuitry 200 will comprise N capacitors and a switch network comprising 2N switches. A series-connected pair of switches is coupled in parallel with each of the N cells, and each of the N capacitors is coupled at a first terminal to a node between a respective pair of switches and at a second terminal to a common node.

As will be appreciated by those skilled in the art, because the capacitors 232-236 of the cell balancing circuitry 200 are coupled in parallel between the switch network 210 and the common node 240, in the event that one of the capacitors 232-236 fails, the risk of damage to any of the cells 112-114 is greatly reduced, because none of the cells 112-114 is short-circuited.

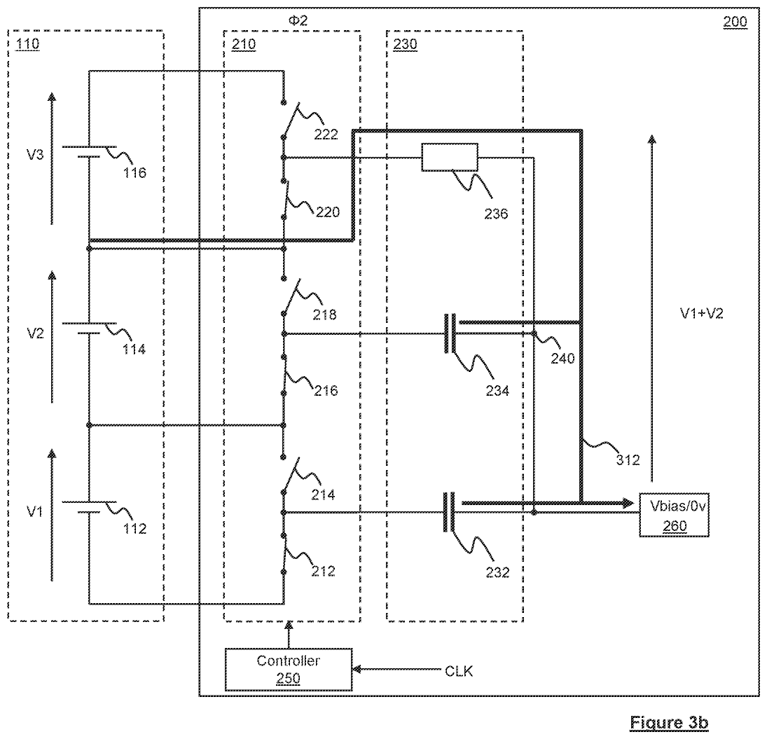

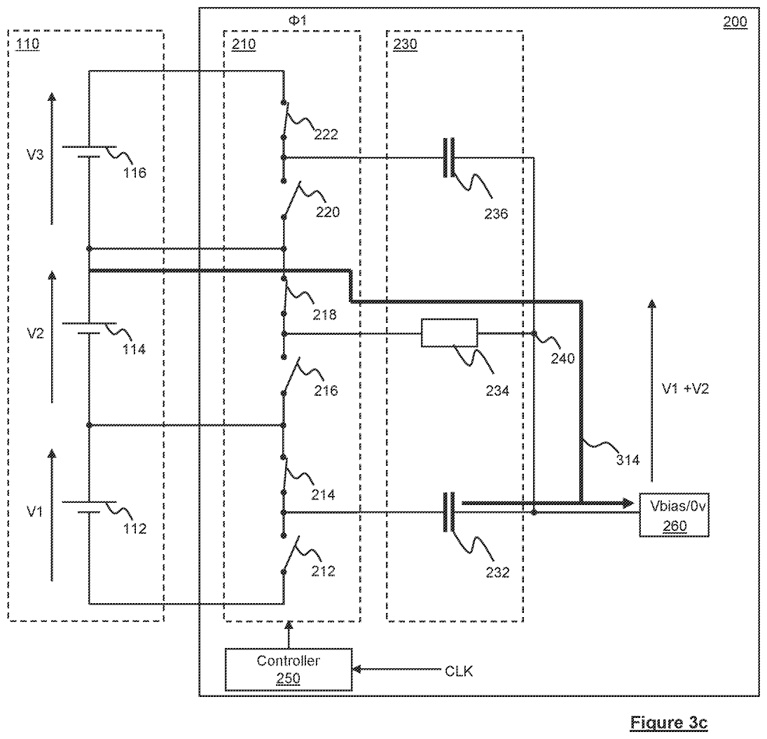

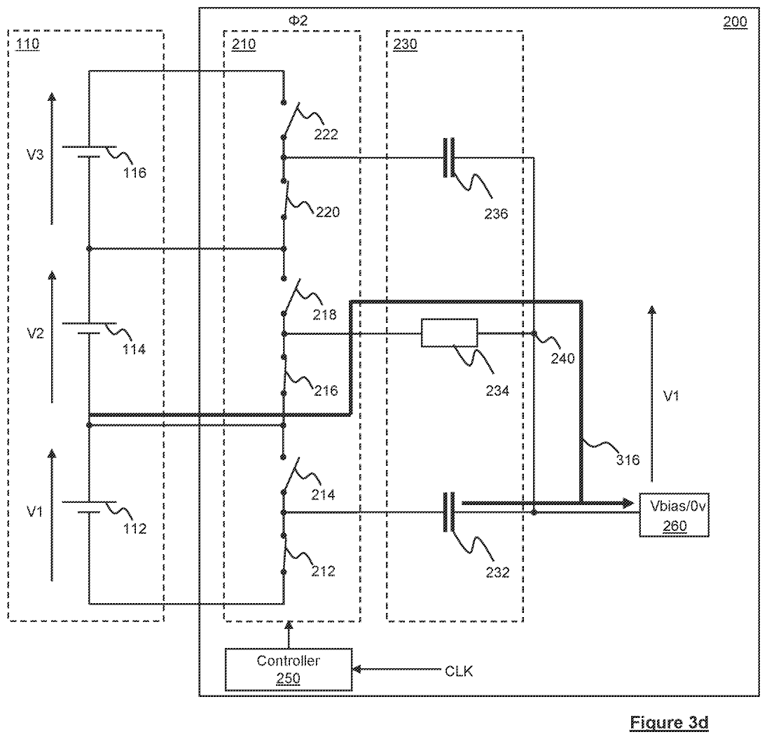

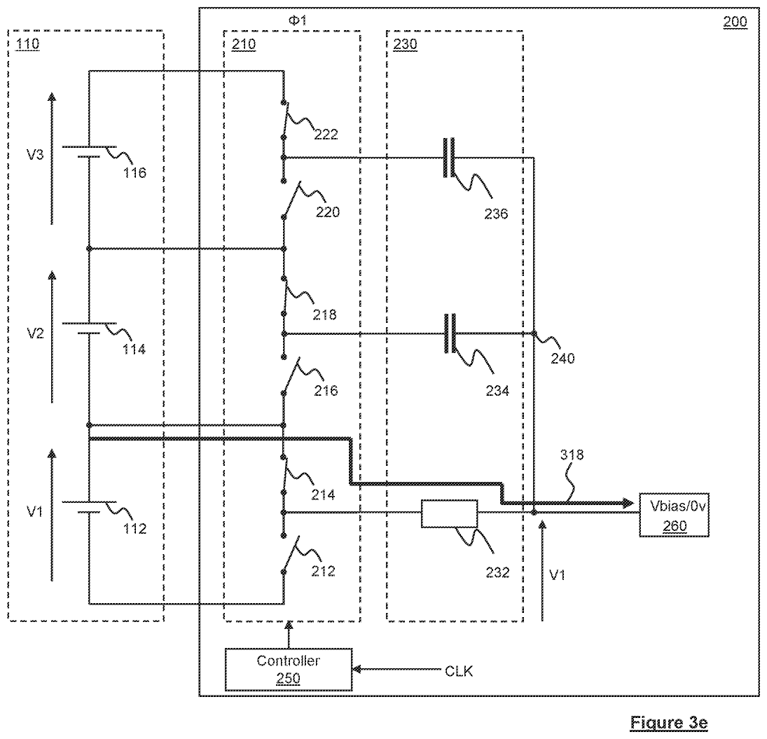

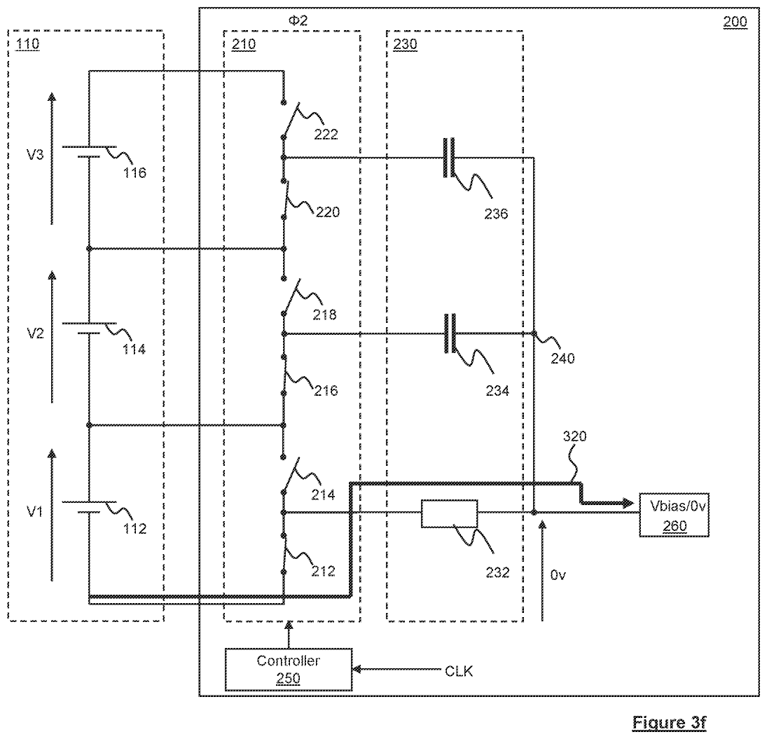

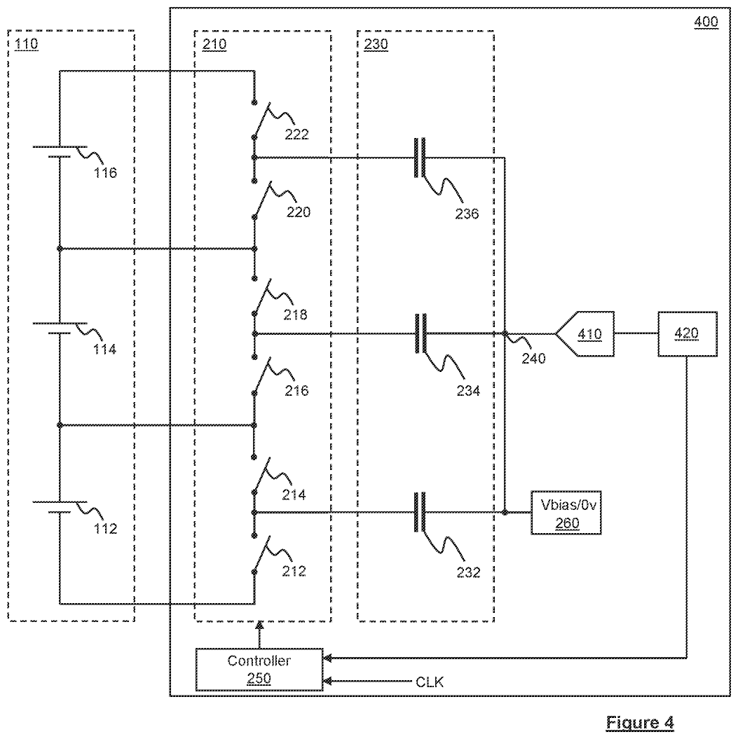

This is illustrated in FIGS. 3a-3f, which show the cell balancing circuitry 200 of FIG. 2a in various states in which one of the capacitors 232-236 has failed as a short circuit.

In FIG. 3a, the third capacitor 236 has failed as a short circuit during the first phase of operation, and thus the third capacitor 236 is depicted in FIG. 3a by a resistor representing the resistance of the shorted capacitor. Thus, during the first phase of operation in this capacitor failure scenario a current path 310 exists from a first terminal of the third cell 116 through the sixth switch 222 and the third capacitor 236 to the voltage source 260 and the second terminals of the first and second capacitors 232, 234. A voltage equal to V1+V2+V3 (where V1, V2, V3 are the voltages of the first, second and third cells 112-116 respectively) develops at the common node 240.

In FIG. 3b, the third capacitor 236 has failed as a short circuit during the second phase of operation, and thus the third capacitor 236 is depicted in FIG. 3b by a resistor representing the resistance of the shorted capacitor. Thus, during the second phase of operation in this capacitor failure scenario a current path 312 exists from a second terminal of the third cell 116 through the fifth switch 220 and the third capacitor 236 to the voltage source 260 and the second terminals of the first and second capacitors 232, 234. A voltage equal to V1+V2 develops at the common node 240.

In FIG. 3c, the second capacitor 234 has failed as a short circuit during the first phase of operation, and thus the second capacitor 234 is depicted in FIG. 3c by a resistor representing the resistance of the shorted capacitor. Thus, during the first phase of operation in this capacitor failure scenario a current path 314 exists from a second terminal of the second cell 114 through the fourth switch 218 and the second capacitor 234 to the voltage source 260 and the second terminal of the first capacitor 232. A voltage equal to V1+V2 develops at the common node 240.

In FIG. 3d, the second capacitor 234 has failed as a short circuit during the second phase of operation, and thus the second capacitor 234 is depicted in FIG. 3d by a resistor representing the resistance of the shorted capacitor. Thus, during the second phase of operation in this capacitor failure scenario a current path 316 exists from a first terminal of the second cell 114 through the third switch 216 and the second capacitor 234 to the voltage source 260 and the second terminal of the first capacitor 232. A voltage equal to V1 develops at the common node 240.

In FIG. 3e, the first capacitor 232 has failed as a short circuit during the first phase of operation, and thus the first capacitor 232 is depicted in FIG. 3e by a resistor representing the resistance of the shorted capacitor. Thus, during the first phase of operation in this capacitor failure scenario a current path 318 exists from a second terminal of the first cell 112 through the second switch 214 and the first capacitor 232 to the voltage source 260. A voltage equal to V1 develops at the common node 240.

In FIG. 3f, the first capacitor 232 has failed as a short circuit during the second phase of operation, and thus the first capacitor 232 is depicted in FIG. 3f by a resistor representing the resistance of the shorted capacitor. Thus, during the second phase of operation in this capacitor failure scenario a current path exists 320 from a first terminal of the first cell 112 through the first switch 212 and the first capacitor 232 to the voltage source 260. A voltage equal to the voltage at the first terminal of the first cell 112 (which in the illustrated example is shown as 0v) develops at the common node 240.

As will be apparent from FIGS. 3a-3f, in the illustrated short-circuit failure situations none of the cells 112-116 are short-circuited, and so the risk of damage to the first cell is greatly reduced, in comparison with the risk that arises if the capacitor 132 of the cell balancing circuitry of FIG. 1a fails as a short circuit.

By monitoring the voltage at the common node 240, failure of a capacitor 232-236 as a short circuit can be detected, and appropriate action can be taken to stop using the failed capacitor in balancing operations, and to notify a user of a host device incorporating the cell balancing circuitry of the failure.

FIG. 4 is a schematic representation of cell balancing circuitry according to the present disclosure. The cell balancing circuitry, shown generally at 400 in FIG. 4, includes many elements in common with the cell balancing circuitry 200 of FIG. 2a. Such common elements are denoted by common reference numerals in FIGS. 2a and 4 and will not be described again here for the sake of clarity and conciseness.

The cell balancing circuitry 400 in the example illustrated in FIG. 4 includes analog to digital converter (ADC) circuitry 410 having an input coupled to the common node 240. An output of the ADC circuitry 410 is coupled to an input of detection circuitry 420. Thus, the ADC circuitry 410 provides a digital signal indicative of the voltage at the common node 240 to the detection circuitry 420.

The detection circuitry 420 is configured to monitor the voltage at the common node 240 (as represented by the digital signal output by the ADC circuitry 410) and to detect a fault (e.g., a short-circuit) in a capacitor of the set of capacitors 230 based on the monitored voltage.

In normal operation of the cell balancing circuitry 400 (i.e., when none of the capacitors 232-236 has failed or developed a fault), the voltage at the common node 240 is equal to (or close to) the bias voltage supplied by the voltage source 260. In embodiments that do not include the voltage source 260, the voltage at the common node 240 in normal operation of the cell balancing circuitry 400 remains stable at an expected voltage or within an expected voltage range.

In contrast, as explained above with reference to FIGS. 3a-3f, when one of the capacitors 232-236 has developed a fault or failed as a short circuit, the voltage at the common node 240 differs from the expected voltage or voltage range.

In particular, the voltage at the common node modulates between different values, depending upon which capacitor has failed, over the first and second phases Φ1, Φ2 of operation of the cell balancing circuitry 400. In general, for a set of cells comprising N cells, where the cell balancing circuitry comprises N capacitors, if the nth capacitor fails as a short circuit (where n=1 for the lowermost capacitor of the set—i.e. in the example of FIG. 4 n=1 for the first capacitor 232), then the voltage at the common node 240 alternates between a value of nVcell in the first phase and a value of (n−1)Vcell in the second phase, where VCell is the average voltage of a single one of the cells.

The detection circuitry 420 is configured to compare the monitored voltage at the common node 240 to an expected voltage or voltage range (e.g., the bias voltage supplied by the voltage source 260, if provided, or a predefined expected voltage or voltage range for embodiments that omit the voltage source 260). If the monitored voltage at the common node 240 differs from the expected voltage or voltage range, the detection circuitry 420 may generate a fault detection signal for outputting to the control circuitry 250.

In response to the fault detection signal the control circuitry 250 may cause all of the switches 212-222 to open, thereby decoupling all of the capacitors from the set of cells 110.

The control circuitry 250 may then cause each of the switches 212-222 to close in turn (while holding the other switches open) while the detection circuitry 420 monitors the voltage at the common node 240 to identify which capacitor(s) has failed or developed a fault, by detecting a change from the expected voltage or voltage range when a particular switch is closed.

For example, if the third capacitor 236 has failed as a short circuit, the detection circuitry 420 will detect a difference between an expected voltage (e.g., Vbias) at the common node 240 and the actual voltage at the common node 240 when either the fifth switch 220 or the sixth switch 222 is closed. Similarly, if the second capacitor 234 has failed as a short circuit, the detection circuitry 420 will detect a difference between the expected voltage and the actual voltage at the common node 240 when either the third switch 216 or the fourth switch 218 is closed, and if the first capacitor 232 has failed as a short circuit the detection circuitry 420 will detect a difference between the expected voltage and the actual voltage at the common node 240 when either the first switch 212 or the second switch 214 is closed.

Closing each of the switches in turn in this way can provide confirmation of a fault in or failure of a capacitor. For example, a change in the voltage at the common node 420 when the sixth switch 222 is closed may be indicative of a fault in the third capacitor 236, and this may be confirmed if a change in the voltage at the common node 420 is detected when the sixth switch 222 is opened and the fifth switch 220 is closed. However, in some examples the control circuitry 250 may be operable to close alternate switches (e.g. the first, third and fifth switches, or the second, fourth and sixth switches) in turn while the voltage at the common node 420 is being monitored, such that a a fault or failure of a capacitor can be detected without subsequent confirmation.

If the detection circuitry 420 detects a short-circuit fault or failure of one of the capacitors 232-236 in this way (either with or without confirmation), the detection circuitry 420 may generate a flag signal, which may be output to the control circuitry 250 to cause the control circuitry 250 to stop using that capacitor in the cell balancing process, by holding the associated switches open. Thus, if the detection circuitry 420 detects a short-circuit fault or failure of the first capacitor 232, it may output a flag signal to the control circuitry 250. In response, the control circuitry 250 may hold the first and second switches 212, 214 open, thereby excluding the first capacitor 232 from the cell balancing process. Similarly, if the detection circuitry 420 detects a short-circuit fault or failure of the second capacitor 234, it may output a flag signal to the control circuitry 250 to cause the control circuitry 250 may hold the second and third switches 216, 218 open to exclude the second capacitor 234 from the cell balancing process, and if the detection circuitry 420 detects a short-circuit fault or failure of the third capacitor 236, it may output a flag signal to the control circuitry 250 to cause the control circuitry 250 to hold the fifth and sixth switches 220, 222 open, thereby excluding the third capacitor 236 from the cell balancing process.

Thus, by monitoring the voltage at the common node 240 during operation of the cell balancing circuitry 400, the detection circuitry 420 is able to detect when a short-circuit failure or fault occurs in one of the capacitors 232-236, by detecting a difference between the monitored voltage of the common node 240 and an expected voltage or voltage range at the common node.

Having detected a fault or failure, the detection circuitry 420 can subsequently identify which of the capacitor(s) is affected by the fault or failure, by detecting which of capacitors, when coupled individually to the common node 240, cause a change from an expected voltage or voltage range at the common node 240. The detection circuitry 420 can then flag the affected capacitor(s) so that they can be excluded by the control circuitry 250 from the cell balancing process.

The process described above may be performed during operation of the cell balancing circuitry 400, and may also be performed on start-up of the cell balancing circuitry 400. Thus, on start-up of the cell balancing circuitry 400 all of the switches 212-222 may be open. With the cell balancing circuitry 400 coupled to set of cells 110 each switch (or alternative switches) may be closed in turn, and the voltage at the common node 240 may be detected and compared to an expected voltage by the detection circuitry 420 to identify and flag any failed or faulty capacitors prior to commencing operation of the cell balancing circuitry 400. In this way failed capacitors can be flagged and excluded from the cell balancing process prior to operation of the cell balancing circuitry 400.

In an alternative (or additional) approach, the detection circuitry 420 may monitor the voltage at the common node 240 during each phase of operation of the cell balancing circuitry 400. If the detection circuitry 420 detects a modulation between nVCell and (n−1)VCell of the voltage at the common node in successive phases of operation (which, as described above, is indicative of a short-circuit failure or fault affecting the nth cell), the detection circuitry 420 may flag the nth capacitor has failed or faulty, so that it can be excluded from the cell balancing process as described above. By monitoring the voltage at the common node 240 in this way, any failed or faulty capacitor can be identified without the need to stop the cell balancing process.

As will be appreciated, the voltages V1, V2, V3 of the cells 112-116 are not constant, but will vary as the cells 112-116 become discharged through use, and as a result of the cell balancing performed by the cell balancing circuitry 400. Thus, the average cell voltage VCell is also not constant. The detection circuitry 420 may receive information on the voltages V1-V3 and/or the average cell voltage VCell from a battery management system (BMS) of a host device incorporating the set of cells 110 and the cell balancing circuitry 400. Alternatively, the detection circuitry 420 may be programmed with, or may calculate or otherwise determine, upper and lower limit values for VCell, based on battery specifications, and these upper and lower limit values may be used in determining whether a modulation between nVCell and (n−1)VCell of the voltage at the common node in successive phases of operation has been detected.

Flagging the capacitor(s) as faulty or failed (either prior to or during operation of the cell balancing circuitry 400) may also trigger a notification or warning to the user of a host device incorporating the set of cells 110 and the cell balancing circuitry 400. For example, if the host device is an electric vehicle a notification or warning could be issued to the user via a vehicle status monitoring system.

The example cell balancing circuitry 400 shown in FIG. 4 includes separate detection circuitry 420 and control circuitry 250, but it will be appreciated that the functionality of the detection circuitry 420 could be incorporated into the control circuitry 250.

Additionally, although the example cell balancing circuitry 400 shown in FIG. 4 includes ADC circuitry that outputs a digital representation of the voltage at the common node 240, in other examples this ADC circuitry 410 may be omitted, such that an analog representation of the voltage at the common node 240 is received by the detection circuitry 420 or the control circuitry 250.

As will be apparent from the foregoing discussion, the present disclosure provides a switched-capacitor cell balancing system in which a fault in or failure of a capacitor does not lead to a short-circuit of a cell of a battery or battery pack to which the cell balancing system is coupled, due to the coupling of the capacitors in parallel between the switch network and the common node. Moreover, any capacitor that is subject to such a fault or failure can be identified and excluded from the cell balancing process, and can be flagged as faulty or failed to prompt appropriate remedial action.

In the forgoing discussion the present disclosure is presented in the context of balancing the voltage and/or state of charge of the constituent cells of batteries or battery packs used in electric vehicles. As will be apparent to those of ordinary skill in the art, the principles of the present disclosure are equally applicable to rechargeable battery packs, battery modules and batteries used in other devices, apparatus or applications, e.g., cordless power tools, computing devices such as laptop, tablet and netbook computers, portable devices such as mobile telephones and the like. Thus, the present disclosure is not limited to battery packs and associated charging systems and methods for electric vehicles, but extends to battery packs, battery modules, batteries and associated charging systems and methods for other applications, devices or apparatus.

The cell balancing system described above with reference to the accompanying drawings may be provided or incorporated in a host device such as an electric vehicle such as a car, motorcycle, goods vehicle, bicycle, or scooter, a mobility vehicle such as a wheelchair, mobility scooter or other mobility aid, a cordless tool, a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

Alternatively, the cell balancing system described above with reference to the accompanying drawings may be provided with or incorporated in a battery, battery module or battery pack comprising a plurality of cells.

The cell balancing circuitry of the present disclosure may be implemented as one or more integrated circuits (ICs). For example, an IC may include the switch network 210, control circuitry 250, ADC circuitry 410 and detection circuitry 420, and the capacitors 232-236 may be provided externally of the IC. Alternatively, the capacitors 232-236 may be included in the IC. As a further alternative, a first IC may include the switch network and a second IC may include the control circuitry 250, ADC circuitry 410 and detection circuitry 420, with the capacitors 232-236 being provided either on the first IC, on the second IC, or externally of the first and second ICs. The skilled person will be readily able to devise alternative ways of distributing the constituent parts of the cell balancing circuitry of the present disclosure over one or more ICs.

The present disclosure extends to a module comprising a first integrated circuit comprising the switches that make up the switch network 210 and the capacitors 232-236. The module may include a second integrated circuit comprising the control circuitry 250, ADC circuitry 410 and detection circuitry 420, or alternatively the control circuitry 250, ADC circuitry 410 and detection circuitry 420 may be provided in the first integrated circuit.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications, embodiments will be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog™ or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. Cell balancing circuitry for balancing a set of cells, the cell balancing circuitry comprising:
a switch network configured for coupling to the cells;
a set of capacitors coupled in parallel between the switch network and a common node; and
detection circuitry configured to detect a fault in a capacitor of the set of capacitors based on a voltage at the common node.

2. Cell balancing circuitry according to claim 1, wherein the detection circuitry is configured to output a signal indicative of a fault in a capacitor if the voltage at the common node differs from an expected voltage.

3. Cell balancing circuitry according to claim 1, wherein the switch network comprises a plurality of switches configured to selectively couple a first terminal of each capacitor of the set of capacitors to a first terminal or a second terminal of a respective different cell of the set of cells.

4. Cell balancing circuitry according to claim 3, further comprising control circuitry configured to control operation of the plurality of switches of the switch network.

5. Cell balancing circuitry according to claim 4, wherein the control circuitry is configured to receive a clock signal and to synchronise operation of the switches to cycles of the clock signal.

6. Cell balancing circuitry according to claim 3, wherein the control circuitry is operable, when the switch network is coupled to a set of cells prior to operation of the cell balancing circuitry, or in response to detection of a fault in a capacitor during operation of the cell balancing circuitry, to:
decouple the set of capacitors from the set of cells; and
subsequently couple a capacitor of the set of capacitors to the set of cells, and wherein the detection circuitry is operable to monitor the voltage at the common node and to identify that the capacitor is affected by the fault if the voltage at the common node changes when the capacitor is coupled to the set of cells.

7. Cell balancing circuitry according to claim 1, wherein the cell balancing circuitry is operable in a first phase in which a first subset of the set of cells is coupled to the set of capacitors and a second phase in which a second subset of the set of cells, different from the first subset, is coupled to the set of capacitors.

8. Cell balancing circuitry according to claim 7, wherein the detection circuitry is configured to monitor a voltage at the common node during operation of the cell balancing circuitry and to identify that a capacitor of the set of capacitors is affected by a fault if a predetermined modulation of the voltage at the common node is detected in successive phases of operation.

9. Cell balancing circuitry according to claim 6, wherein the control circuitry is configured to decouple the identified capacitor from the set of cells.

10. Cell balancing circuitry according to claim 9 wherein the control circuitry is configured to hold open switches associated with the identified capacitor.

11. Cell balancing circuitry according to claim 1, wherein the cell balancing circuitry further comprises a voltage source for supplying a bias voltage to the common node.

12. A method for detecting a fault in a capacitor of a set of capacitors of cell balancing circuitry comprising a switch network and a set of capacitors in which each capacitor of the set of capacitors is coupled in parallel between the switch network and a common node, the method comprising:
with the cell balancing circuitry coupled to a set of cells, closing a switch of the switch network in turn to couple a capacitor of the set of capacitors to the common node;
detecting a voltage at the common node when the capacitor is coupled to the common node; and
if the voltage at the common node differs from an expected voltage or voltage range when the capacitor is coupled to the common node, identifying that the capacitor is affected by a fault.

13. A method for detecting a fault in a capacitor of a set of capacitors of cell balancing circuitry comprising a switch network and a set of capacitors in which each capacitor of the set of capacitors is coupled in parallel between the switch network and a common node and the cell balancing circuitry is operable in a first phase in which a first subset of the set of cells is coupled to the set of capacitors and a second phase in which a second subset of the set of cells, different from the first subset, is coupled to the set of capacitors, the method comprising:
monitoring a voltage at the common node during operation of the cell balancing circuitry; and
identifying that a capacitor of the set of capacitors is affected by a fault if a predetermined modulation of the voltage at the common node is detected in successive phases of operation.

14. An integrated circuit comprising cell balancing circuitry according to claim 1.

15. A host device comprising cell balancing circuitry according to claim 1.

16. A host device according to claim 15, wherein the host device comprises an electric vehicle, an electric bicycle, a wheelchair, an electric scooter, a cordless power tool, a computing device, a laptop, notebook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

17. A battery or battery pack comprising cell balancing circuitry according to claim 1.

18. An integrated circuit comprising a switch network for cell balancing circuitry according to claim 1.

19. An integrated circuit according to claim 18 further comprising control circuitry for controlling the switch network.

20. A module comprising an integrated circuit according to claim 19 and a set of capacitors.
